(19) United States
(12) Patent Application Publication
(10) Pub. No.: US 2026/0324390 A1
(43) Pub. Date: Oct. 15, 2026

(54) DUAL VIA STRUCTURE FOR THROUGH-CHIP CONNECTIONS

(71) Applicant: Taiwan Semiconductor Manufacturing Company, Ltd., Hsinchu (TW)

(72) Inventors: Chieh-En Chen, Tainan City (TW); Chen-Hsien Lin, Tainan City (TW); Shyh-Fann Ting, Tainan City (TW)

(21) Appl. No.: 19/719,359

(22) Filed: Jun. 25, 2026

Related U.S. Application Data
(62) Division of application No. 18/354,244, filed on Jul. 18, 2023.

(51) Int. Cl. H10W 20/20; H10W 20/00; H10W 20/42; H10W 20/43

(52) U.S. Cl. CPC H10W 20/20; H10W 20/023; H10W 20/42; H10W 20/43

(57) ABSTRACT

Some embodiments relate to an integrated circuit device incorporating a dual via structure for through-chip connections. The integrated circuit device includes a substrate, at least one dielectric layer disposed over a frontside surface of the substrate, and a plurality of metal layers residing in the at least one dielectric layer. The integrated circuit device also includes a first via structure and a second via structure. The first via structure includes a plurality of vias. The first via structure is electrically connected to one of the plurality of metal layers and extends through the frontside surface of the substrate. The second via structure extends from a backside surface of the substrate opposite the frontside surface into the substrate and contacts the first via structure.

### REFERENCE TO RELATED APPLICATION

This Application is a Divisional of U.S. application Ser. No. 18/354,244, filed on Jul. 18, 2023, the contents of which are hereby incorporated by reference in their entirety.

### BACKGROUND

The use of through-silicon vias (TSVs) (or, alternatively, through-chip vias) in integrated circuit (IC) devices has enabled the passing of signals vertically through ICs, thus enhancing the development of high-performance three-dimensional (e.g., stacked) devices by way of an increase in connection density, as well as a shortening of connection length, between ICs.

As IC technology continues to evolve, corresponding connection structures are often updated to maintain compatibility with the IC devices in which the connections are implemented.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of some embodiments of an IC device employing a dual via structure to facilitate through-chip connections, according to the present disclosure.

FIG. 2 illustrates a cross-sectional view of some embodiments of an IC device employing a dual via structure for through-chip connections.

FIGS. 3-14 illustrate cross-sectional views of some embodiments of a semiconductor structure for an IC device employing a dual via structure for through-chip connections at various stages of manufacture.

FIGS. 9A and 9B illustrate plan views of some embodiments of a portion of a semiconductor structure for an IC device employing a dual via structure for through-chip connections at associated stages of manufacture.

FIG. 15 illustrates a methodology of forming an IC device employing a dual via structure for through-chip connections in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Varying types of TSVs are employed in some IC devices. Two such types include “via-last” TSVs (or back TSVs (BTSVs)) and “via-middle” TSVs (or mid TSVs (MTSVs)). Typically, BTSVs extend from a backside surface of the IC substrate through the substrate directly by way of a relatively large, angled trench to a metal layer positioned over a frontside surface of the substrate opposite the backside surface. MTSVs are typically created by way of forming a single large via (e.g., by way of vertical etching) through the opposing (frontside) surface of the substrate to the backside surface.

As IC technology progresses, typical BTSVs and MTSVs have become less effective as through-chip via solutions in some configurations. For example, the use of thin metal layers reduces the acceptable landing window (e.g., the acceptable variation in depth) of the large backside trench associated with BTSVs. Further, the exposure of extreme-low-K (ELK) dielectrics (e.g., sometimes employed in back-end-of-line (BEOL) IC processing over the frontside of the substrate) to moisture as a result of etching the large backside trench may cause reliability issues in the dielectrics. Generally, ELK dielectrics facilitate the use of relatively thin dielectric layers that provide a correspondingly lower parasitic capacitance, thus enabling higher circuit switching speeds in advanced IC devices that employ such dielectrics.

MTSVs are also becoming more problematic, particularly at the edge of the wafer. More specifically, by virtue of its relatively deep and wide frontside via, the copper typically employed for the via may be completely missing or only partially present after typical copper electro-chemical plating (ECP) edge bevel removal (EBR) processing of the wafer. EBR processing typically involves the removal of copper or other metal from the edge of the wafer to prevent flaking of metal from the wafer, as well as improvement of adherence of additional layers to the wafer. More generally, the relatively large volume of copper associated with the depth and width of an MTSV may be associated with an enhanced probability of deformation (e.g., creation or one or more nodules) following the thermal processes typically associated with IC fabrication.

To address these issues, the present disclosure provides some embodiments of an IC device that includes a dual via structure for through-chip connections. More specifically, in some embodiments, such an IC device may include a first via structure created by way of the frontside surface of the substrate that is connected with a second via structure formed by way of the backside surface of the substrate. In some embodiments, the first via structure may not be implemented as a single deep and wide via (e.g., as a result of not extending through the entire substrate for a subsequent packaging process), thereby mitigating against missing or corrupted metal produced by the via. Further, in some embodiments, the second via structure may not be as deep as a typical BTSV, and thus may not directly affect any metal layers or ELK dielectrics.

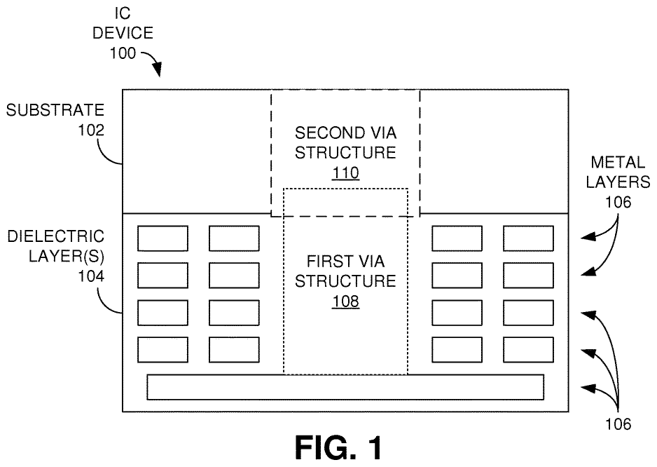

FIG. 1 illustrates a schematic diagram of some embodiments of an IC device 100 employing a dual via structure to facilitate through-chip connections, according to the present disclosure. IC device 100 may include a substrate 102 and one or more dielectric layers 104 with a plurality of metal layers 106 residing therein over a frontside surface of the substrate 102. Within that configuration, the IC device 100 may also include a first via structure 108 that extends from, and is electrically connected to, one of the plurality of metal layers 106. The IC device 100 may also include a second via structure 110 extending from a backside surface of the substrate 102 opposite the frontside surface into the substrate 102 and contacting the first via structure 108. In some embodiments, by employing both the first via structure 108 and the second via structure 110 in tandem, neither the first via structure 108 nor the second via structure 110 requires the depth and corresponding potential problems typically associated with other TSVs, such as the BTSVs and MTSVs discussed above.

While a single through-chip via structure pair including the first via structure 108 and the second via structure 110 are discussed above and below, IC device 100 may be include several or many such through-chip via structures in other embodiments.

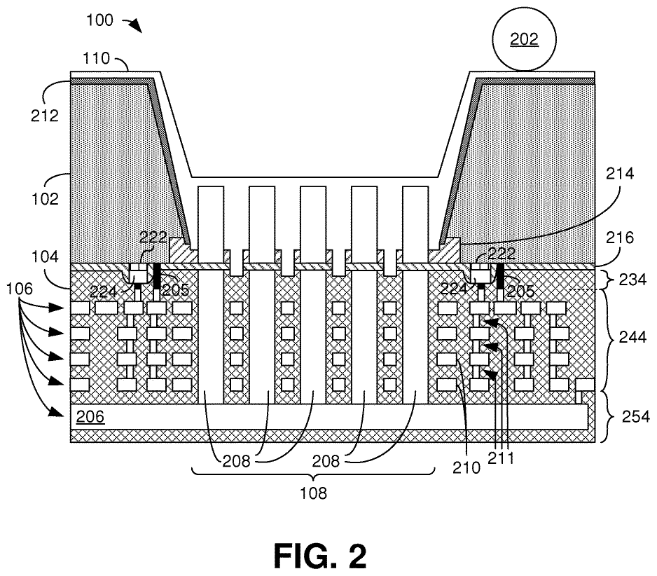

FIG. 2 illustrates a cross-sectional view of some embodiments of the IC device 100 employing a dual via structure for through-chip connections. In some embodiments, IC device 100 may include substrate 102, in which multiple doped (or active) regions (not shown in FIG. 2) may be implanted or otherwise formed. In some embodiments, the doped regions may include regions in the substrate 102 where sources and/or drains for transistors may be formed. Also, in some embodiments, at least one shallow trench isolation (STI) region 214 may reside in the substrate 102 (e.g., between transistors, diodes, and the like to prevent or limit electrical current leakage between adjacent semiconductor device components). For example, the at least one STI region 214 may be positioned between transistors, at least some of which may include a gate structure 224 separated from the substrate 102 by an oxide structure 222, and/or may include one or more source/drain connections to the substrate 102. In some embodiments, additional semiconductor components other than transistors may be employed.

Disposed over the frontside surface of the substrate 102 (e.g., downward from substrate 102 from the perspective of FIG. 2) may be a barrier structure 216 (e.g., silicon nitride (SiN), serving as an insulator and/or chemical/diffusion barrier for substrate 102). Disposed above the barrier structure 216 may be the one or more dielectric layers 104 including the plurality of metal layers 106. Each metal layer 106 may include one or more metal structures 210, some of which may be connected to metal structures 210 of an adjacent metal layer 106 by way of vias 211. Also, in some embodiments, contacts 205 may connect component structures (e.g., gate structures 224, direct connections to substrate 102, etc.) to vias 211 and/or metal structures 210 of a first of the metal layers 106. Moreover, in some embodiments, the one or more dielectric layers may include a first interlayer dielectric (ILD) 234, a second ILD 244, and an additional ILD 254 that may be formed of the same or different materials, possess the same or varying properties (e.g., dielectric constants), and so on.

Also shown in FIG. 2, in some embodiments, the first via structure 108 may include a plurality of vias 208 electrically connected to one of the metal layers 106 (e.g., a top metal layer 206). In some embodiments, the plurality of vias 208 may also extend through one or more of the metal layers 106 and the frontside surface of substrate 102. In the particular embodiments of FIG. 2, the plurality of vias 208 may also extend through the at least one STI region 214 (e.g., into substrate 102). In some embodiments, the plurality of vias 208 may include a particular metal (e.g., copper or an alloy including copper).

While the number of the plurality of vias 208 explicitly illustrated in FIG. 2 is five, other numbers of the plurality of vias 208 greater or less than five may be employed in other embodiments. Further, in some embodiments, when viewed in a plan view of IC device 100, the plurality of vias 208 may be arranged two-dimensionally, such as in a plural number of rows and columns. Moreover, in some embodiments, the number of the plurality of vias 208, as well as the size (e.g., width) of each individual via 208, may be configured depending on the particular needs of the IC device 100 in terms of signal connectivity, power consumption, and so on.

Contacting the first via structure 108 may be a second via structure 110 extending from a backside surface of the substrate 102 into the substrate 102. As depicted in FIG. 2, the second via structure 110 may be a metallic layer disposed over an etched region extending from the backside surface of the substrate 102 into the substrate 102. In some embodiments, the second via structure 110 may also cover an adjoining or surrounding portion of the backside surface of the substrate 102. In some embodiments, the second via structure 110 may be partially or completely isolated from the substrate 102 by way of a dielectric structure 212, such as an oxide layer. Also, in some embodiments, the second via structure 110 may make contact with (e.g., “land on”) the barrier structure 216, as illustrated in FIG. 2. In yet other embodiments, the second via structure 110 may penetrate the barrier structure 216 and “land on” an adjacent surface of the one or more dielectric layers 104.

In some embodiments, the second via structure 110 may be copper or another metal. Also, in some embodiments, the second via structure 110 may be the same, or nearly the same, metal employed for the plurality of vias 208 of the first via structure 108.

In some embodiments, the second via structure 110 may surround and make contact with an end portion of each of the plurality of vias 208, thus providing a significant contact surface area between the first via structure 108 and the second via structure 110 for enhanced conductivity.

Also shown in FIG. 2 is an example connection mechanism (e.g., a solder ball 202) coupled to the second via structure 110, which may facilitate an electrical connection of the die that includes the IC device 100 with another die, a package for the IC device 100, or another circuit or component.

Based on the dual via structure discussed above in conjunction with the IC device 100 of FIGS. 1 and 2, in some embodiments, the first via structure 108 may provide a significant reduction in critical distances pertaining to both the maximum width of each portion of the first via structure 108 (e.g., vias 208) and the maximum length of the first via structure 108 that extends into the region defined by the substrate 102 compared to other MTSV structures that are wider and extend deeper into the substrate 102. This reduction may result in a reduced likelihood of metal nodule formation, missing or corrupted metallic material (e.g., due to ECP EBR processing of the wafer), or other abnormalities associated with the vias. Relatedly, in some embodiments, the reduced length of the first via structure 108 may substantially mitigate against the need to reduce the thickness of the substrate 102 that is sometimes associated with MTSVs that traverse the entirety of the substrate 102, potentially resulting in a reduced probability of breakage or other damage to the IC device 100.

Furthermore, use of the second via structure 110 may negate the possibility of exposing an ELK dielectric (e.g., one of the one or more dielectric layers 104) as a result of connecting directly with a metal layer 106 therein, as is typical with a BTSV. Instead, as described above, the landing region for the second via structure 110 is in the neighborhood of the interface between the substrate 102 and the one or more dielectric layers 104 (e.g., at or near the barrier structure 216) prior to encountering a metal layer 106.

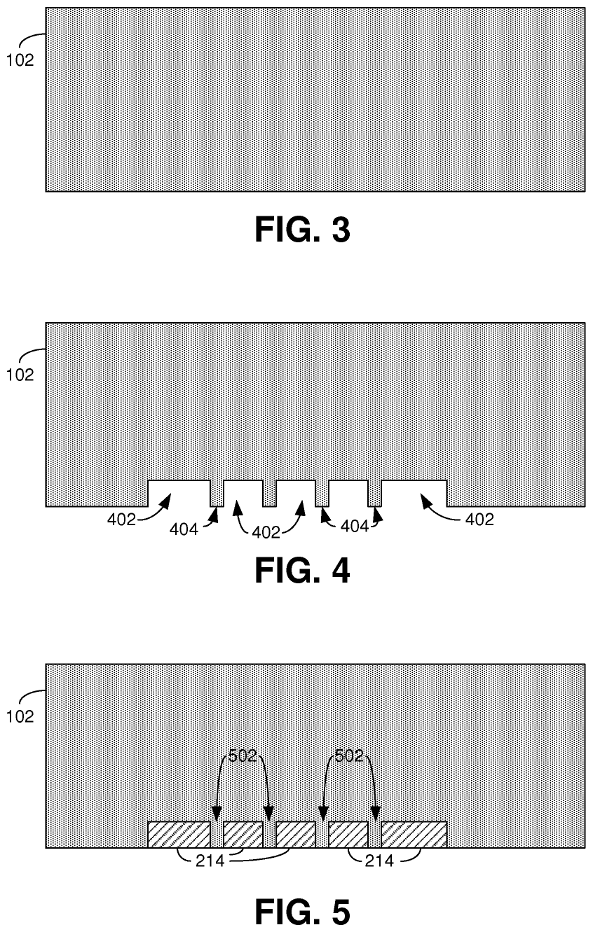

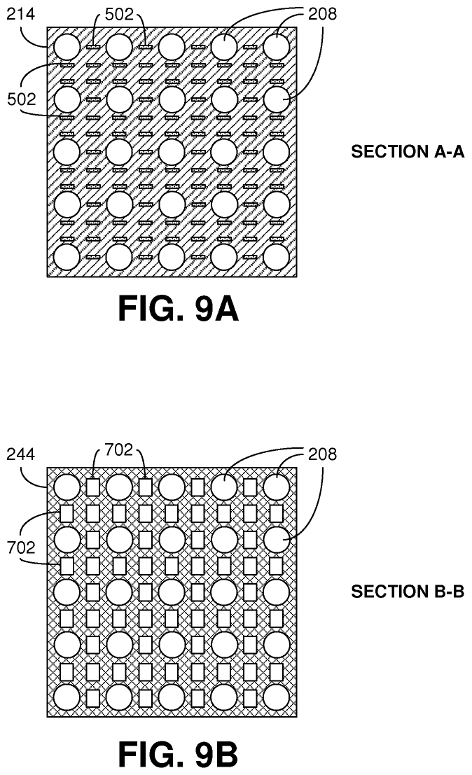

FIGS. 3-14 illustrate cross-sectional views of some embodiments of a semiconductor structure for the IC device 100 at various stages of manufacture. In addition, FIGS. 9A and 9B illustrate plan views of some embodiments of a portion of a semiconductor structure for the IC device 100 at associated stages of manufacture. Although FIGS. 3-14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 3 illustrates a portion of the substrate 102 that may serve as the base structure upon which additional processing acts, as depicted in FIGS. 4-14, may be performed. The substrate 102 may be a p-doped silicon (p-Si) substrate, although other materials may be employed in other embodiments. Also, in some embodiments, the substrate 102 manifests as a semiconductor wafer. After processing is completed (e.g., as described below in connection with FIGS. 4-14), such a wafer may be optionally stacked with other wafers and then singulated into individual dice that correspond to individual IC devices 100.

FIG. 4 illustrates creation (e.g., etching) of one or more trenches 402, and FIG. 5 illustrates the forming of at least one shallow trench isolation (STI) region 214 within trenches 402. In some embodiments, the at least one STI region 214 may include a dielectric (e.g., silicon dioxide (SiO₂)). While more than one STI region 214 is indicated in the cross-sectional view of FIG. 5, the STI regions 214 may be interconnected to form a single STI region 214. In some embodiments, the at least one STI region 214, in operation, may limit or prevent leakage current therethrough. Moreover, the forming of the at least one STI region 214 may be followed by chemical-mechanical planarization (CMP) to the corresponding (e.g., frontside) surface of the substrate 102 that includes the at least one STI region 214. In some embodiments, the at least one STI region 214 is dimensioned to allow small regions of the substrate 102 (e.g., substrate regions 404 of FIG. 4) to remain therebetween. Accordingly, a plurality of doped regions 502 may be formed (e.g., implanted) within those small regions (e.g., after the formation of the at least one STI region 214). The inclusion of the doped regions 502 may facilitate adherence to a design rules manual (DRM) as it relates to a doped region pattern being generated in the substrate 102. (As used herein, a doped (or active) region may be any active semiconductor region of the substrate, such as doped n-regions or p-regions for transistor sources and drains, as well as channel regions therebetween positioned under a gate structure.) The doped region pattern employed within the area of the at least one STI region 214 may thus be somewhat consistent with the doped region pattern used in other areas of the substrate 102, as may be required by the DRM.

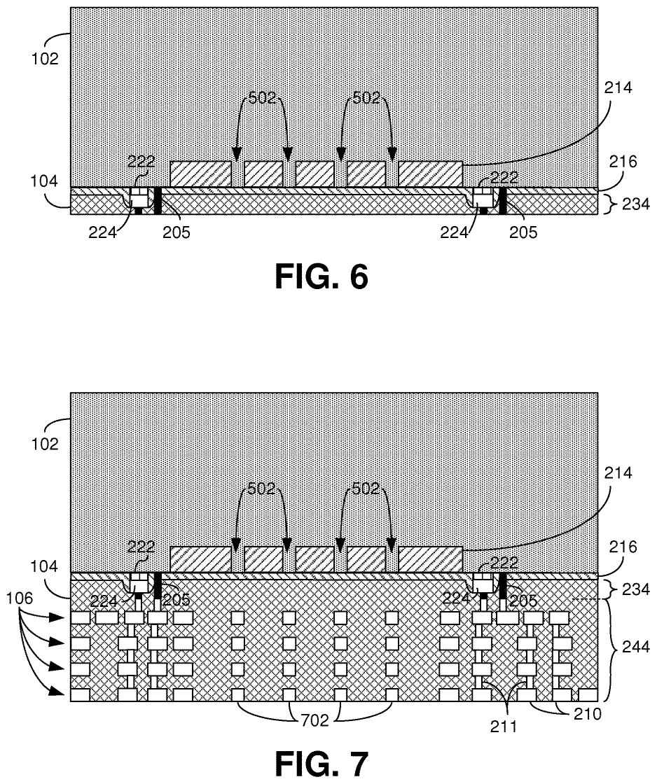

FIG. 6 illustrates formation of active and/or passive components, such as diodes, transistors, resistors, and so on, over the frontside surface of the substrate 102, and outside the region occupied by the at least one STI region 214. As indicated in FIG. 6, one or more of the components may include, for example, an oxide structure 222 formed over the substrate 102, followed by formation of a gate structure 224 (e.g., metal, polycrystalline silicon, or the like).

Thereafter, formed over the substrate 102 and the various structures mentioned above (e.g., oxide structures 222, gate structures 224, and the like) may be the barrier structure 216 (e.g., silicon nitride (SiN)) followed by formation of one or more dielectric layers 104. The barrier structure 216 may be employed as an electrical insulator and/or chemical barrier to isolate the substrate 102 from the dielectric layers and metal structures formed thereabove. In some embodiments, the barrier structure 216 may also form sidewall spacer structures about oxide structures 222, gate structures 224, and so on.

In some embodiments, the first of the at least one dielectric layer 104 (e.g., silicon dioxide (SiO₂)) to be formed may be the first interlayer dielectric (ILD) 234. Formed within the first ILD 234 (e.g. by way of etching and subsequent filling) may be a plurality of contacts 205 for connecting with the gate structures 224, the substrate 102, and the like.

FIG. 7 illustrates formation of the second ILD 244 over the first ILD 234, with one or more vias 211 and associated metal structures 210 of a plurality of metal layers 106 created therein (e.g., by etching and associated filling) for connecting to the plurality of contacts 205 and other structures in the first ILD 234. In some embodiments, the second ILD 244 may be an extreme-low-K (ELK) dielectric, in which K refers to the dielectric constant of the material.

Further, in each of the metal layers 106, a plurality of metal structures 702 may be formed among the locations in which the plurality of vias 208 are to be constructed. The metal structures 702 may at least somewhat align with other metal structures of the second ILD 244 in other areas of the IC device (e.g., those areas that include metal structures 210 attached to other metal structures 210, vias 211, or functional components). Consequently, this alignment may facilitate adherence to design rules related to the forming of metal structures throughout the IC device 100. In some embodiments, the metal structures 702 may not be electrically or functionally coupled with each other, other metal structures 210, or other active regions or components of the IC device, and thus may be referred to as “dummy” (DMY) metal structures 702.

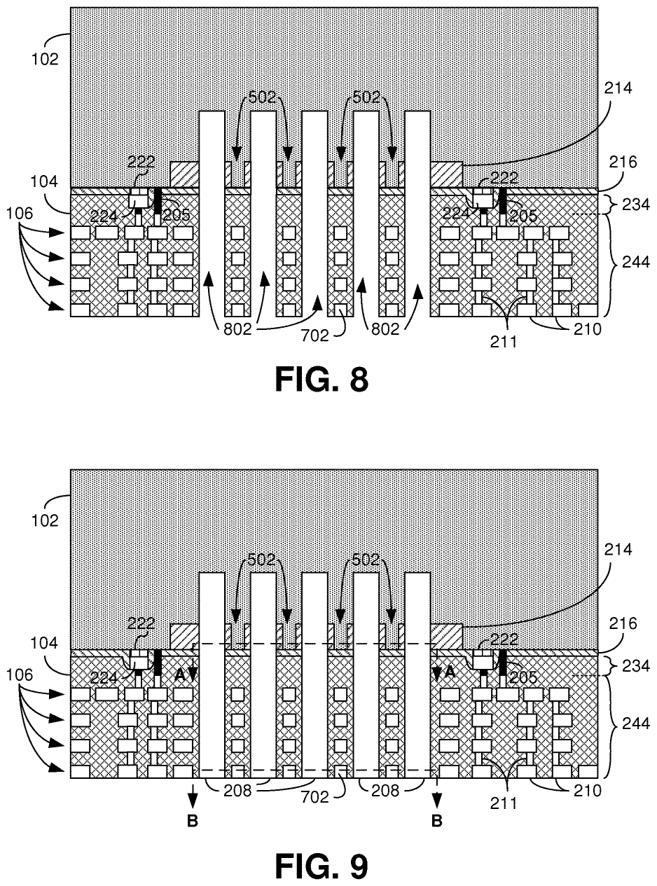

FIG. 8 illustrates creation (e.g., etching) of via voids 802, and FIG. 9 illustrates the formation in the via voids 802 of the plurality of vias 208 that constitute the first via structure 108. In some embodiments, the depth of the plurality of vias 208 into the substrate 102 may depend on one or more characteristics of the electrical connection being provided by the plurality of vias 208 (e.g., the functionality of the connection, such as a control or status signal, a data signal, a power connection, etc.) within the IC device 100. In some embodiments, the plurality of vias 208 may extend into the substrate 102 approximately 20-50 percent, or more particularly, 30-40 percent, of the thickness of the substrate 102. Additionally, in some embodiments, the depth of the plurality of vias 208 may extend two-to-three times the depth of the STI regions 214.

Accordingly, unlike typical MTSV technology, the plurality of vias 208 extend into substrate 102 with a shallow depth and a small volume. As a result, the possibility of the metal (e.g., copper) of the plurality of vias 208 being partially or completely missing after typical ECP EBR processing of the wafer may be reduced. Also, the probability of generating unwanted nodules or other metal deformations, as discussed above, may be limited as well.

FIG. 9A illustrates a plan view of some embodiments of the plurality of vias 208 along line A-A of FIG. 9. In some embodiments, each of the plurality of vias 208 may be circular in cross-section, although other shapes (square, rectangular, etc.) may be possible in other embodiments. Further, in some embodiments, the plurality of vias 208 may be arranged as a two-dimensional array including a plurality of rows and columns. However, other arrangements employing different patterns for the placement of the plurality of vias 208 are also possible. Additionally, while FIG. 9A depicts twenty-five vias 208 in a 5-by-5 array, other numbers of vias 208 may be employed in other embodiments. The number of vias 208, in some embodiments, may be based on one or more characteristics of the electrical connection being provided by the plurality of vias 208 (e.g., as described above), as well as the width of each of the plurality of vias 208. For example, when smaller widths are used for the plurality of vias 208, a higher number of vias 208 may be employed for the same type of electrical connection to be provided by the plurality of vias 208.

In some embodiments, the width of each of the plurality of vias 208 may be a critical dimension (CD) that is limited to help prevent the introduction of defects, such as those discussed above. For example, compared to the width of a typical MTSV, the width of each of the plurality of vias 208 may be relatively small to prevent problems normally associated with MTSVs (e.g., the loss of metal in the vias 208 due to ECP EBR processing of the wafer, the creation of nodules or other metal deformations, and the like).

Also, as shown in FIG. 9A, the spacing of the plurality of vias 208 in the plan view may facilitate the placement of the doped regions 502 (e.g., within the substrate regions 404 illustrated in FIG. 4) in both the row and column directions. In some embodiments, the doped regions 502 may at least somewhat align with other doped regions formed in the substrate 102 in other areas of the IC device (e.g., those areas that include functional transistors and other semiconductor components). As indicated above, this alignment may facilitate adherence to design rules related to the forming of doped regions through the IC device 100. In some embodiments, the doped regions 502 may not be electrically or functionally coupled with other active regions or components of the IC device 100, and thus may be referred to as “dummy” (DMY) doped regions.

FIG. 9B illustrates a plan view of some embodiments of the plurality of vias 208 and the plurality of metal structures 702 within the second ILD 244 along line B-B of FIG. 9. In some embodiments, the spacing of the plurality of vias 208 in the plan view may facilitate the placement of the metal structures 702 in both the row and column directions. Further, the metal structures 702 may at least somewhat align with other metal structures 210 of the second ILD 244 in other areas of the IC device 100 (e.g., those areas that include metal structures 210 attached to other metal structures 210, vias 211, or functional components). Consequently, this alignment may facilitate adherence to design rules related to the forming of metal structures through the IC device 100. In some embodiments, the metal structures 702 may not be electrically or functionally coupled with each other, other metal structures, or other active regions or components of the IC device 100, and thus may be referred to as “dummy” (DMY) metal structures 702.

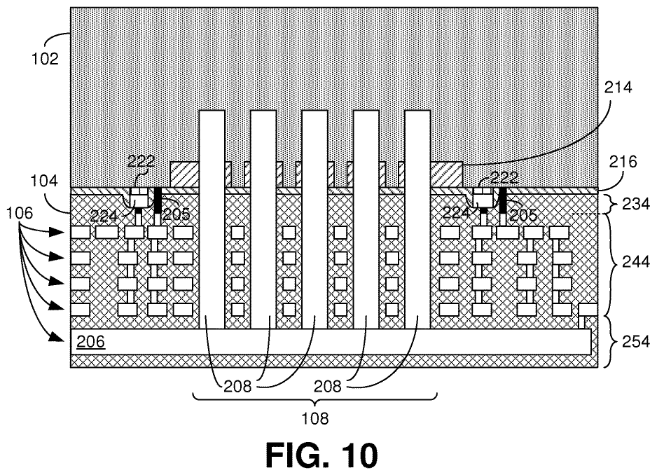

FIG. 10 illustrates formation (e.g., by etching and subsequent deposition) of the additional ILD 254 (e.g., formed of a low-K (LK) dielectric material) that includes an additional metal layer 106 (e.g., a top metal layer 206) coupled to each of the plurality of vias 208 of the second via structure 108. Generally, LK dielectrics have a lower dielectric constant than that of silicon dioxide, while ELK dielectrics have a low dielectric constant relative to those of LK dielectrics.

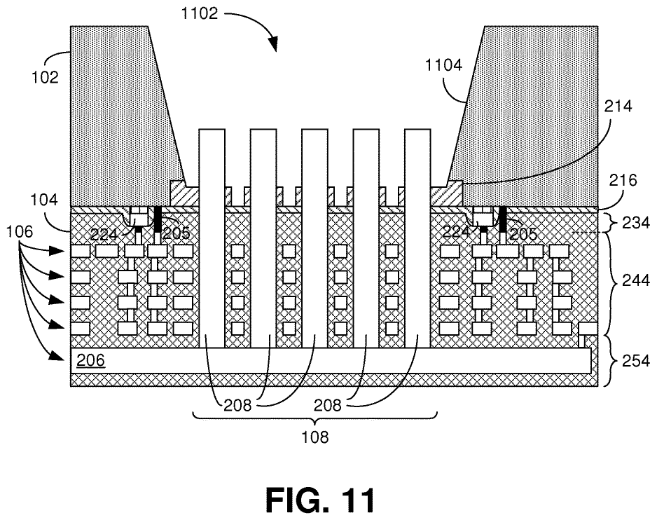

FIGS. 11 through 14 illustrate the formation of the second via structure 110 referenced in FIG. 1. FIG. 11, for example, illustrates the etching of the substrate 102 by way of the backside surface of the substrate 102 to form an etched region 1102 corresponding with the plurality of vias 208 of the first via structure 108. In some embodiments, the etched region 1102 includes a sloped sidewall 1104. Also, in some embodiments, the etched region 1102 may extend from the backside surface of the substrate 102 to the barrier structure 216 (e.g., as shown in FIG. 11). In some embodiments, the etching of the etched region 1102 may be configured to remove the intended portions of the substrate 102, including those portions between the plurality of vias 208, without significantly affecting the STI regions 214, the barrier structure 216, or the plurality of vias 208. In some embodiments, as indicated in FIG. 2, the etched region 1102 may extend through the barrier structure 216, and possibly into the first ILD 234.

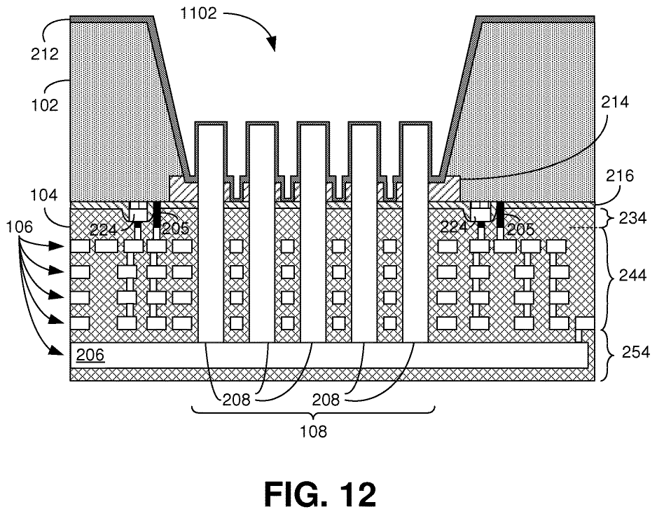

FIG. 12 illustrates the forming (e.g., deposition) of the dielectric structure 212 (e.g., an oxide layer) over the etched region 1102 and some surrounding area of the backside surface of the substrate 102. In some embodiments, the dielectric structure 212 may cover each of the plurality of vias 208 and the at least one STI region 214 encompassed by the etched region 1102.

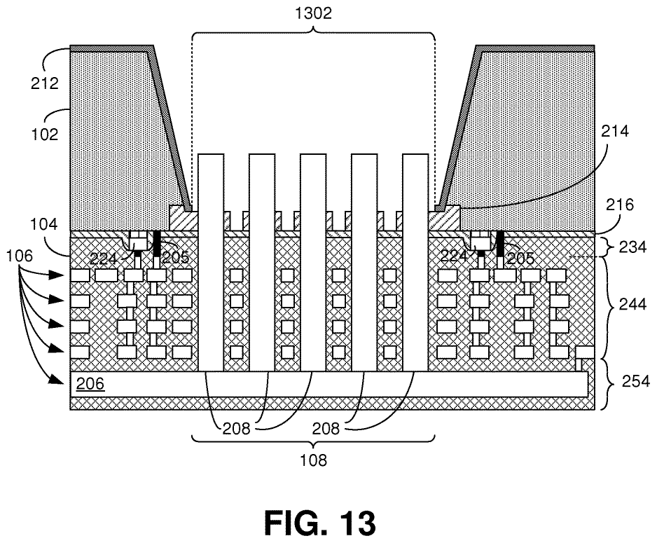

FIG. 13 illustrates the etching of a portion 1302 of the dielectric structure 212 from the etched region 1102. In some embodiments, the portion 1302 of the dielectric structure 212 covering the barrier structure 216, the plurality of vias 208, and portions of the at least one STI region 214 adjacent the plurality of vias 208 may be etched, thus allowing at least the portions of the dielectric structure 212 covering the substrate 102 to remain.

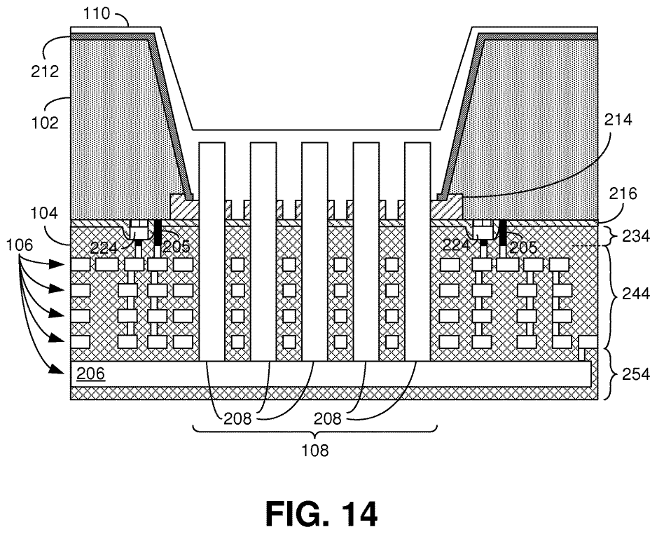

FIG. 14 illustrates the forming (e.g., deposition) of the second via structure 110 over the plurality of vias 208, the at least one STI region 214, and the remaining portion of the dielectric structure 212. In some embodiments, the second via structure 110 does not directly contact the substrate 102, as the dielectric structure 212 isolates the second via structure 110 from the substrate 102 to prevent any leakage current therebetween. Further, in some embodiments, the second via structure 110 is of sufficient depth within the vicinity of the plurality of vias 208 to completely cover each of the plurality of vias 208, thus potentially maximizing the contact surface between the first via structure 108 and the second via structure 110.

In some embodiments, the metal employed in the second via structure 110 (e.g., copper) is the same as or similar to the metal employed in the plurality of vias 208 of the first via structure 108.

Also, in some embodiments, by restricting the depth of the etched region 1102 of FIG. 11 to the barrier structure 216 or in the vicinity thereof, any potential problems with exposing an ELK dielectric to moisture or a narrow landing window associated with the use of thin metal layers within at least one dielectric layer 104, which are associated with typical BTSVs, are eliminated.

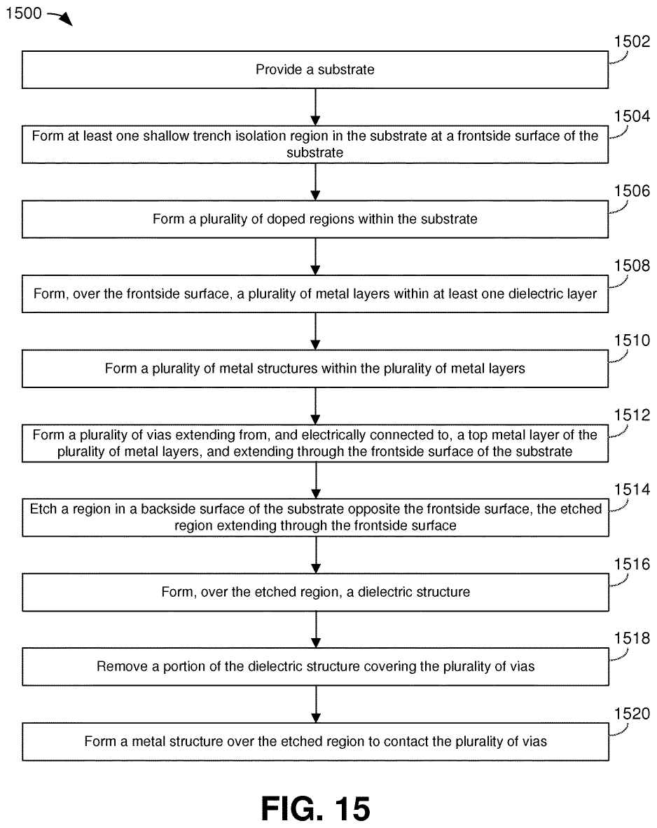

FIG. 15 illustrates a methodology 1500 of forming an IC device with a dual via structure for through-chip connections in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

Acts 1502 through 1520 may correspond, for example, to the structure previously illustrated in FIGS. 3 through 14 in some embodiments. At Act 1502, a substrate (e.g., substrate 102) may be provided. FIG. 3 illustrates a cross-sectional view of some embodiments corresponding to Act 1502.

At Act 1504, at least one shallow trench isolation (STI) region (e.g., at least one STI region 214) may be formed in the substrate at a frontside surface of the substrate. FIGS. 4 and 5 illustrate cross-sectional views of some embodiments corresponding to Act 1504.

At Act 1506, a plurality of doped regions (e.g., DMY doped regions 502) may be formed within the substrate 102. FIG. 5 illustrates a cross-sectional view of some embodiments corresponding to Act 1506.

At Act 1508, a plurality of metal layers (e.g., metal layers 106) may be formed over the frontside surface of the substrate within at least one dielectric layer (e.g., dielectric layer(s) 104). FIGS. 6, 7, and 10 illustrate cross-sectional views of some embodiments corresponding to Act 1508.

At Act 1510, the plurality of metal structures (e.g., DMY metal structures 702) may be formed within the at least one dielectric layer. FIG. 7 illustrates cross-sectional views of some embodiments corresponding to Act 1510.

At Act 1512, a plurality of vias (e.g., plurality of vias 208) may be formed to extend from, and electrically connect to, a top metal layer (e.g., top metal layer 206) of the plurality of metal layers, and to extend through the frontside surface of the substrate. FIGS. 8, 9, and 10 illustrate cross-sectional views of some embodiments corresponding to Act 1512.

At Act 1514, an etched region (e.g., etched region 1102) may be formed in a backside surface of the substrate opposite the frontside surface, where the etched region extends through the frontside surface. FIG. 11 illustrates a cross-sectional view of some embodiments corresponding to Act 1514.

At Act 1516, a dielectric structure (e.g., dielectric structure 212) may be formed over the etched region. FIG. 12 illustrates a cross-sectional view of some embodiments corresponding to Act 1516.

At Act 1518, a portion of the dielectric structure (e.g., portion 1302) covering the plurality of vias may be removed. FIG. 13 illustrates a cross-sectional view of some embodiments corresponding to Act 1518.

At Act 1520, a metal structure (e.g., second via structure 110) may be formed over the etched region to contact the plurality of vias. FIG. 14 illustrates a cross-sectional view of some embodiments corresponding to Act 1520.

Some embodiments relate to an integrated circuit device. The integrated circuit device includes a substrate, at least one dielectric layer disposed over a frontside surface of the substrate, and a plurality of metal layers residing in the at least one dielectric layer. The integrated circuit device also includes a first via structure and a second via structure. The first via structure includes a plurality of vias. The first via structure is electrically connected to one of the plurality of metal layers and extends through the frontside surface of the substrate. The second via structure extends from a backside surface of the substrate opposite the frontside surface into the substrate and contacts the first via structure.

Some embodiments relate to other integrated circuit devices (e.g., frontside illuminated (FSI) CMOS light sensor devices and backside illuminated (BSI) light sensor devices). In some embodiments, the integrated circuit device (e.g., an FSI CMOS light sensor device) includes a substrate having a frontside surface and a backside surface opposite the frontside surface. The substrate defines an etched region in the backside surface that extends through the frontside surface. In other embodiments, the integrated circuit device is a BSI CMOS light sensor device bonded with a logic device. The logic device includes a substrate having a frontside surface which connects to a frontside surface of the sensor device by bonding, and a backside surface opposite the frontside surface. The substrate defines an etched region in the backside surface of the logic device that extends through the frontside surface. The integrated circuit device also includes at least one dielectric layer disposed over the frontside surface of the substrate. The at least one dielectric layer incorporates a plurality of metal layers. The integrated circuit device also includes a plurality of vias. Each of the plurality of vias is electrically connected to a top metal layer of the plurality of metal layers. Each of the plurality of vias also extends through a remaining one or more of the plurality of metal layers and the frontside surface of the substrate. The integrated circuit device also includes a metal structure extending from the backside surface into the substrate, covering the etched region, and contacting the plurality of vias.

Some embodiments relate to a method of manufacturing an integrated circuit device. The method includes providing a substrate, and forming, over a frontside surface of the substgrate, a plurality of metal layers within at least one dielectric layer. The method also includes forming a plurality of vias electrically connected to a top metal layer of the plurality of metal layers and extending through the frontside surface of the substrate. The method also includes etching a region in a backside surface of the substrate opposite the frontside surface, where the etched region extends through the frontside surface. The method further includes forming a metal structure over the etched region, the metal structure contacting the plurality of vias.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a substrate;
at least one dielectric layer disposed over a frontside surface of the substrate;
a plurality of metal layers residing in the at least one dielectric layer;
a first via structure comprising a plurality of vias, the first via structure electrically connected to one of the plurality of metal layers and extending through the frontside surface of the substrate; and
a second via structure extending from a backside surface of the substrate opposite the frontside surface into the substrate and contacting the first via structure.

2. The integrated circuit device of claim 1, wherein:
the plurality of metal layers comprises a top metal layer and at least one additional metal layer positioned between the top metal layer and the substrate; and
the first via structure extends from, and is electrically connected to, the top metal layer.

3. The integrated circuit device of claim 1, wherein:
each of the plurality of vias is directly connected to the one of the plurality of metal layers and extends into the substrate.

4. The integrated circuit device of claim 3, wherein:
the plurality of vias are arranged in a two-dimensional array in a plan view of the substrate.

5. The integrated circuit device of claim 3, further comprising:
a plurality of doped regions distributed among the plurality of vias within the substrate, wherein the plurality of doped regions are electrically isolated.

6. The integrated circuit device of claim 3, further comprising:
a plurality of metal structures distributed among the plurality of vias within at least one of the plurality of metal layers, wherein the plurality of metal structures are electrically isolated.

7. The integrated circuit device of claim 1, further comprising:
at least one shallow trench isolation (STI) region disposed in the substrate at the frontside surface, wherein the plurality of vias extend through the at least one STI region.

8. The integrated circuit device of claim 1, wherein:
the substrate defines an etched region extending from the backside surface and into the substrate; and
the second via structure covers the etched region.

9. The integrated circuit device of claim 8, further comprising:
at least one shallow trench isolation (STI) region disposed in the substrate at the frontside surface, wherein the second via structure contacts the at least one STI region in the etched region.

10. The integrated circuit device of claim 9, wherein the second via structure extends over a portion of the backside surface of the substrate.

11. The integrated circuit device of claim 1, further comprising:
a dielectric structure isolating the first via structure from the substrate.

12. An integrated circuit device, comprising:
a substrate having a frontside surface and a backside surface opposite the frontside surface, the substrate having an etched region in the backside surface that extends through the frontside surface;
at least one dielectric layer disposed over the frontside surface of the substrate, the at least one dielectric layer incorporating a plurality of metal layers;
a plurality of vias, each of the plurality of vias electrically connected to a top metal layer of the plurality of metal layers and extending through a remaining one or more of the plurality of metal layers and the frontside surface of the substrate; and
a metal structure extending from the backside surface into the substrate, covering the etched region, and contacting the plurality of vias.

13. The integrated circuit device of claim 12, further comprising:
at least one shallow trench isolation (STI) region disposed in the substrate at the frontside surface, wherein the metal structure and the plurality of vias extend through the at least one STI region.

14. The integrated circuit device of claim 13, further comprising:
a dielectric structure isolating the metal structure from the substrate.

15. A method, comprising:
providing a substrate;
forming, over a frontside surface of the substrate, a plurality of metal layers within at least one dielectric layer;
forming a plurality of vias electrically connected to a top metal layer of the plurality of metal layers and extending through the frontside surface of the substrate;
etching a region in a backside surface of the substrate opposite the frontside surface, the etched region extending through the frontside surface; and
forming a metal structure over the etched region, the metal structure contacting the plurality of vias.

16. The method of claim 15, further comprising:
forming at least one shallow trench isolation (STI) region in the substrate at the frontside surface before forming the plurality of metal layers, wherein the metal structure and the plurality of vias extend through the at least one STI region.

17. The method of claim 15, further comprising:
forming, over the etched region before forming the metal structure, a dielectric structure, the dielectric structure isolating the metal structure from the substrate.

18. The method of claim 15, further comprising:
forming a plurality of doped regions within the substrate among the plurality of vias, wherein the plurality of doped regions are electrically isolated.

19. The method of claim 15, further comprising:
forming a plurality of metal structures within at least one of the plurality of metal layers among the plurality of vias, wherein the plurality of metal structures are electrically isolated.

20. The method of claim 15, wherein:
the plurality of vias are arranged in a two-dimensional array in a plan view of the substrate.
